(19) United States
(12) Patent Application Publication
(10) Pub. No.: US 2024/0353444 A1
(43) Pub. Date: Oct. 24, 2024

(54) PROBE AND INSPECTION SOCKET

(71) Applicants: Yamaichi Electronics Co., Ltd., Ota-ku, Tokyo (JP); Mikuro Spring Co., Ltd., Nagono (JP)

(72) Inventors: Seiya YAMAMOTO, Tokyo (JP); Katsumi SUZUKI, Tokyo (JP); Shinya FUJIMOTO, Nagano (JP)

(21) Appl. No.: 18/687,416

(22) PCT Filed: Aug. 10, 2022
(86) PCT No.: PCT/JP2022/030582

§ 371 Date: Feb. 28, 2024

(30) Foreign Application Priority Data
Sep. 2, 2021 (JP) 2021-142977

(51) Int. Cl. G01R 1/067; G01R 1/04

(52) U.S. Cl. CPC G01R 1/06722; G01R 1/0466

(57) ABSTRACT

Provided are a probe and a socket for inspection that cause the probe to be in direct contact with a housing and are not required to have high dimensional accuracy in the manufacturing thereof. A probe for grounding to be inserted through a through-hole, which is formed in a housing and defined by a metal inner circumferential wall, includes: a probe body including a cylindrical barrel extending in the direction of a first axis and a plunger; and a spring member through which the barrel is inserted, the spring member includes a coil part wound about a second axis, the barrel being inserted through the coil part in the direction of the second axis, and includes a protruding part formed continuously to the coil part and protruding outward from an outer circumferential face of the coil part to be in elastic contact with the inner circumferential wall, and the coil part presses the probe body against the inner circumferential wall by elasticity of the protruding part.

### TECHNICAL FIELD

The present invention relates to a probe and a socket for inspection.

### BACKGROUND ART

In inspection of inspected devices or the like that requires high-speed transmission, a socket for inspection having three types of pins (probes) of a signal pin, a power pin, and a ground pin may be used.

The ground pin is used for electrically connecting a ground terminal of the inspected device and a ground terminal of a test board to a housing as the ground, and an example thereof is disclosed in Patent Literature 1, for example.

Patent Literature 1 discloses a configuration to have electrical conduction between a contact probe for grounding and a metal block as the ground via a coil spring whose axis is made eccentric by a partial change of the diameter.

### CITATION LIST

### Patent Literature

[PTL 1]

Japanese Patent Application Laid-Open No. 2010-060527

### SUMMARY OF INVENTION

### Technical Problem

However, in manufacturing of the coil spring employed in the configuration in Patent Literature 1, it is not easy to control the degree of eccentricity, and it is thus difficult to provide a coil spring which is stably contacted with both members of the contact probe for grounding and the metal block.

Further, since electrical conduction is established via a coil spring, electrical conductivity of the coil spring is essential, which may limit the choice of the material of the coil spring.

Accordingly, the present invention intends to provide a probe and a socket for inspection that cause the probe to be in direct contact with a housing and are not required to have high dimensional accuracy in the manufacturing thereof.

### Solution to Problem

To achieve the above object, the probe and the socket for inspection of the present invention employ the following solutions.

A probe according to one aspect of the present invention is a probe for grounding to be inserted through a through-hole, and the through-hole is formed in a housing and defined by a metal inner circumferential wall. The probe includes: a probe body including a cylindrical barrel extending in a direction of a first axis and a plunger accommodated in the barrel; and a spring member through which the barrel is inserted, the spring member includes a coil part wound about a second axis, the barrel being inserted through the coil part in a direction of the second axis, and includes a protruding part formed continuously to the coil part and protruding outward from an outer circumferential face of the coil part to be in elastic contact with the inner circumferential wall, and the coil part is configured to press the probe body against the inner circumferential wall by elasticity of the protruding part.

According to the probe of the present aspect, the spring member includes a coil part wound about a second axis, the barrel being inserted through the coil part in the direction of the second axis, and includes a protruding part formed continuously to the coil part and protruding outward from an outer circumferential face of the coil part to be in elastic contact with the inner circumferential wall, and the coil part presses the probe body against the inner circumferential wall by elasticity of the protruding part. Thus, when a clearance is present between the through-hole and the probe body, the barrel can be in direct contact with the housing. Accordingly, electrical conduction between the probe body and the housing can be ensured.

Further, since the protruding part of the spring member is in elastic contact with the inner circumferential wall, even when the clearance between the through-hole and the barrel is not constant depending on individuals because of a dimensional error of the through-hole or the barrel, such error can be absorbed. Therefore, high dimensional accuracy is not required in molding the through-hole or manufacturing the barrel.

Further, since the embodiment does not take a configuration to have electrical conduction via the spring member, electrical conductivity or excellent electrical conductivity is not required for the spring member itself. This increases the choice of the material or the manufacturing method of the spring member and can reduce costs. For example, the spring member can be made of an inexpensive resin. Further, it is not required to apply gold plating to the spring member in order to stabilize the contact resistance between the housing and the spring member, and it is thus possible to reduce costs by the cost for the absence of plating.

Further, in the probe according to one aspect of the present invention, the spring member includes two coil parts adjacent to each other in the direction of the second axis, and the protruding part is provided between one of the coil parts and another one of the coil parts adjacent to the one of the coil parts.

According to the probe of the present aspect, the spring member includes two coil parts adjacent to each other in the direction of the second axis, and the protruding part is provided between one of the coil parts and the other of the coil parts adjacent thereto. Thus, the probe body can be pressed against the inner circumferential wall by the two coil parts. In other words, force for pressing the probe body against the inner circumferential wall can be applied to two positions of the barrel by the two coil parts. Accordingly, the probe body can be stably pressed against the inner circumferential wall. In other words, the probe body can be in stable contact with the inner circumferential wall.

Further, in the probe according to one aspect of the present invention, protruding parts are provided at both ends of the coil part in the direction of the second axis.

According to the probe of the present aspect, since protruding parts are provided at both ends of the coil parts in the direction of the second axis, the spring member can be in contact with the inner circumferential wall by the protruding parts at two positions spaced away from each other in the second axis direction. Accordingly, the probe can be stably and forcefully pressed against the inner circumferential wall. Further, it is possible to prevent the spring member from inclining inside the through-hole.

Further, in the probe according to one aspect of the present invention, tips of the protruding parts intersect each other when viewed in the direction of the second axis.

According to the probe of the present aspect, the tips of the protruding parts intersect each other when viewed in the direction of the second axis, and it is thus possible to match the directions in which the restoring forces exerted by respective protruding parts act.

Further, a socket for inspection according to one aspect of the present invention includes: a housing in which a through-hole defined by a metal inner circumferential wall is formed along a direction of a third axis; and the probe inserted through the through-hole along the direction of the third axis, and the coil part is configured to press the probe body against the inner circumferential wall by elasticity of the protruding part.

Further, in the socket for inspection according to one aspect of the present invention, the barrel includes a flange protruding from an outer circumferential face, the through-hole includes a small diameter part having a diameter larger than a portion of the barrel except for the flange and smaller than the flange and a large diameter part having a diameter larger than the flange and being continuous to the small diameter part along the direction of the third axis, the flange is accommodated in the large diameter part of the through-hole, and the spring member is accommodated in the large diameter part between the flange and the small diameter part.

According to the socket for inspection of the present aspect, the barrel includes a flange protruding from an outer circumferential face, the through-hole includes a small diameter part having a diameter larger than a portion of the barrel except for the flange and smaller than the flange and a large diameter part having a diameter larger than the flange and being continuous to the small diameter part along the direction of the third axis, the flange is accommodated in the large diameter part of the through-hole, and the spring member is accommodated in the large diameter part between the flange and the small diameter part. Thus, the flange can be pushed in the direction away from the small diameter part by the elasticity of the coil part along the direction of the second axis. Accordingly, when the socket for inspection is mounted on the test board, a preload can be applied by the elasticity of the coil part.

### Advantageous Effects of Invention

According to the present invention, a probe and a socket for inspection that cause the probe to be in direct contact with a housing and are not required to have high dimensional accuracy in the manufacturing thereof can be provided.

### BRIEF DESCRIPTION OF DRAWINGS

FIG. 1 is a sectional view of a socket including a probe according to a first embodiment.

FIG. 2 is a partial enlarged sectional view of the socket including the probe.

FIG. 3 is a sectional view of a housing.

FIG. 4 is a front view of a probe body (a barrel is illustrated in a longitudinal sectional view).

FIG. 5 is a front view of a spring member.

FIG. 6 is a plan view of the spring member.

FIG. 7 is a longitudinal sectional view before the spring member is inserted into an upper housing.

FIG. 8 is a traverse sectional view taken along a cut line VIII-VIII illustrated in FIG. 7.

FIG. 9 is a longitudinal sectional view when the spring member is inserted into the upper housing.

FIG. 10 is a traverse sectional view taken along a cut line X-X illustrated in FIG. 9.

FIG. 11 is a traverse sectional view taken along a cut line XI-XI illustrated in FIG. 9.

FIG. 12 is a longitudinal sectional view when the probe is inserted into the upper housing.

FIG. 13 is a traverse sectional view taken along a cut line XIII-XIII illustrated in FIG. 12.

FIG. 14 is a longitudinal sectional view before a socket is mounted on a printed wiring board.

FIG. 15 is a longitudinal sectional view when the socket is mounted on the printed wiring board.

FIG. 16 is a longitudinal sectional view when an IC package is secured in the socket.

FIG. 17 is a front view of a spring member according to Modified example 1.

FIG. 18 is a front view of a spring member according to Modified example 2.

FIG. 19 is a plan view of the spring member according to Modified example 2.

FIG. 20 is a front view of a spring member according to Modified example 3.

FIG. 21 is a plan view of the spring member according to Modified example 3.

FIG. 22 is a plan view of the spring member according to Modified example 3.

FIG. 23 is a longitudinal sectional view when a socket including a probe according to a second embodiment is mounted on a printed wiring board.

FIG. 24 is a front view of a probe body according to a third embodiment.

FIG. 25 is a longitudinal sectional view when the probe is inserted into a housing.

FIG. 26 is a longitudinal sectional view when a socket is mounted on the printed wiring board.

FIG. 27 is a longitudinal sectional view when a socket according to a fourth embodiment is mounted on a printed wiring board.

### DESCRIPTION OF EMBODIMENTS

### First Embodiment

A probe and a socket for inspection according to a first embodiment of the present invention will be described below with reference to the drawings.

### Overview of Socket for Inspection

The overview of a socket for inspection 10 (hereafter, simply referred to as the “socket 10”) will be described below.

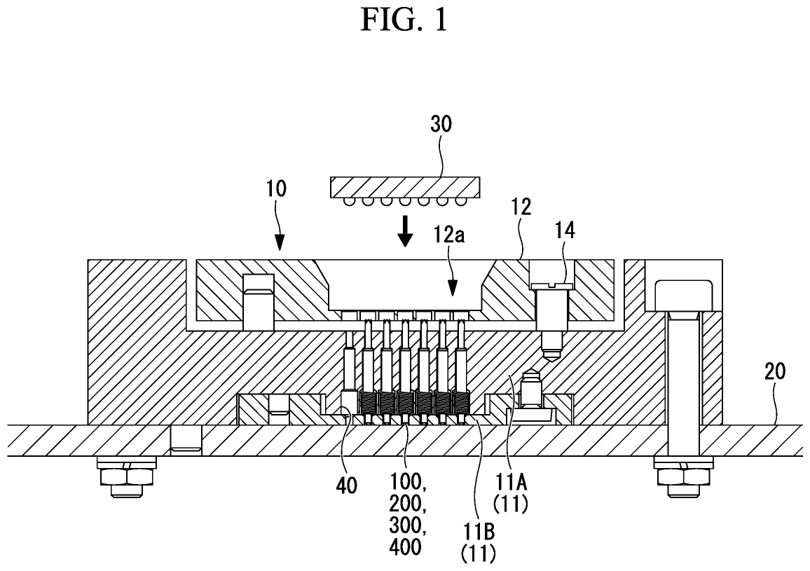

As illustrated in FIG. 1, the socket 10 is a component for causing a printed wiring board (test board) 20 and an IC package (semiconductor package) 30 to have electrical conduction in a test of the IC package 30.

The socket 10 is mounted on the upper face of the printed wiring board 20.

Further, the IC package 30 is secured in a recess 12a formed in a movable base 12 of the socket 10.

Examples of the IC package 30 may be those of a ball grid array (BGA) type. Further, a land grid array (LGA) type or a quad flat package (QFP) type may be employed.

The socket 10 includes a probe 100, a housing 11 having an upper housing 11A and a lower housing 11B, and the movable base 12.

In the socket 10, the housing 11 is arranged on the printed wiring board 20 side, and the movable base 12 is arranged so as to be stacked on the housing 11 (the upper housing 11A).

A pushing member (not illustrated) is interposed between the housing 11 (the upper housing 11A) and the movable base 12 and pushes both the members in directions away from each other.

Further, a base-fixing screw 14 is fixed to the upper housing 11A via the movable base 12 so that the movable base 12 does not fall out (fly out) of the upper housing 11A due to the pushing member.

Accordingly, the movable base 12 is configured to elastically come close to and separate from the housing 11. In detail, the movable base 12 separates from the housing 11 when unloaded, and the movable base 12 comes close to the housing 11 when the movable base 12 is pushed to the housing 11 side.

The housing 11 includes the upper housing 11A and the lower housing 11B and is configured such that the upper housing 11A is stacked on the lower housing 11B.

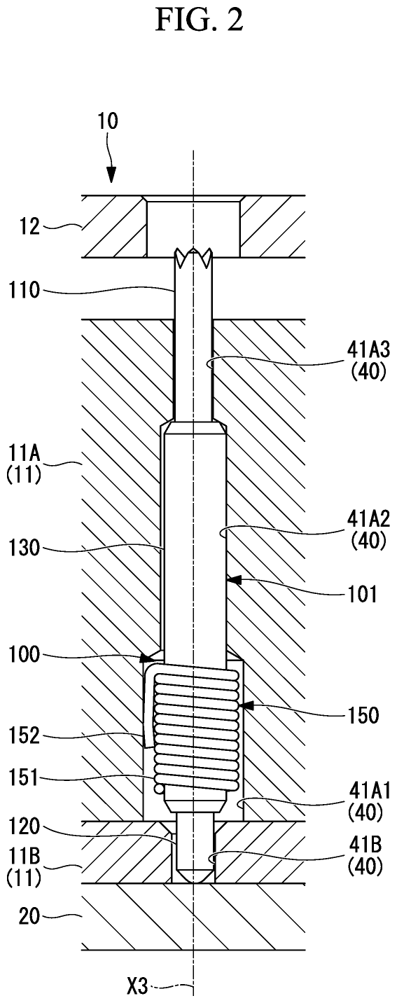

As illustrated in FIG. 1 and FIG. 2, the housing 11 includes a through-hole 40 formed through the upper housing 11A and the lower housing 11B, and the probe 100 is accommodated in the through-hole 40.

Note that the probe 100 is not illustrated in the through-hole 40 illustrated in FIG. 1 (the through-hole 40 on the left side) for simplified illustration.

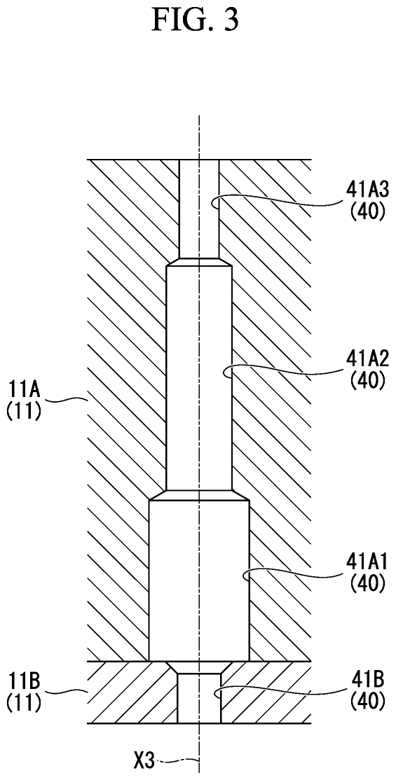

As illustrated in FIG. 3, the through-hole 40 is formed of a large diameter part 41A1, an intermediate diameter part 41A2, and a small diameter part 41A3 formed in the upper housing 11A and a small diameter part 41B formed in the lower housing 11B.

The large diameter part 41A1, the intermediate diameter part 41A2, the small diameter part 41A3, and the small diameter part 41B have an axis X3 (third axis) as a common axis.

In the upper housing 11A, the large diameter part 41A1 has a larger diameter than the intermediate diameter part 41A2. Further, the intermediate diameter part 41A2 has a larger diameter than the small diameter part 41A3.

The small diameter part 41B of the lower housing 11B has a smaller diameter than the large diameter part 41A1 of the upper housing 11A.

The inner circumferential wall of the housing 11 defining the through-hole 40 configured as described above is made of an electrically conductive material (for example, made of metal) and electrically connected to the ground. To achieve this, the housing 11 itself can be made of metal.

### Detail of Probe

The detailed structure of the probe 100 will be described below.

Note that, while there are three types of probes 100 for signal pins, power pins, and ground pins, the probe 100 according to the present embodiment relates to a probe for grounding that electrically connects the ground terminal of the IC package 30 and the ground terminal of the printed wiring board 20 to the housing 11 as the ground.

As illustrated in FIG. 2, the probe 100 includes a probe body 101 and a spring member 150.

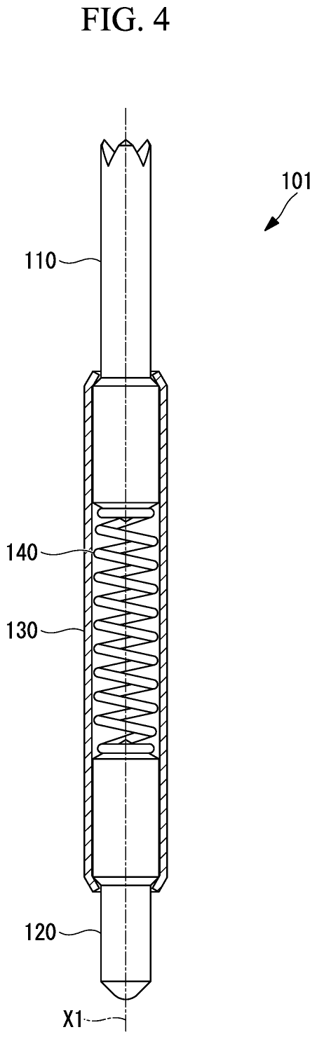

As illustrated in FIG. 4, the probe body 101 includes a barrel 130, an upper plunger 110, a lower plunger 120, and a pushing member 140.

The barrel 130 is a cylindrical member extending in the direction of an axis X1 (first axis).

The barrel 130 is made of metal (for example, a plated cupper-based material).

The barrel 130 has the outer diameter that is smaller than the inner diameter of the intermediate diameter part 41A2 and larger than the inner diameter of the small diameter part 41A3 and the inner diameter of the small diameter part 41B.

The base end portion of the upper plunger 110, the base end portion of the lower plunger 120, and the pushing member 140 are accommodated in the barrel 130.

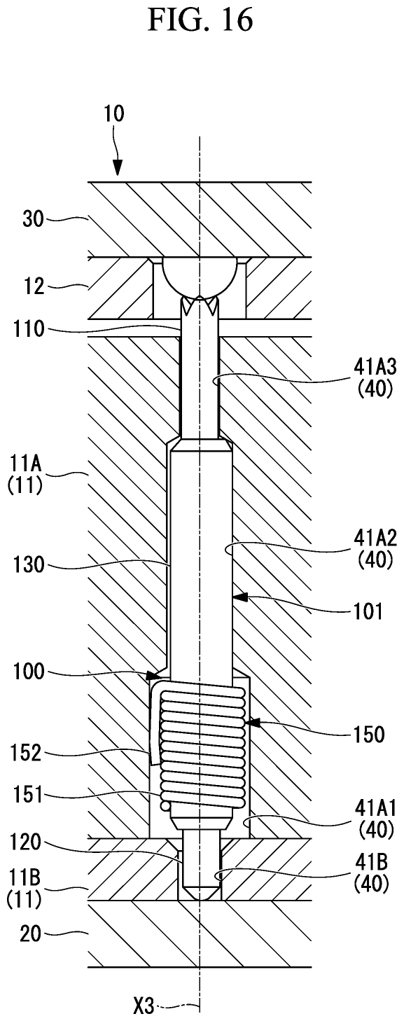

Herein, the base end of the upper plunger 110 refers to an end located on the opposite side to the tip portion contacted with the IC package 30. Further, the base end of the lower plunger 120 refers to an end located on the opposite side to the tip portion contacted with the printed wiring board 20 (see FIG. 16).

The upper plunger 110 and the lower plunger 120 are made of metal (for example, a plated copper-based material). An example of the pushing member 140 may be a metal coil spring (for example, a plated piano wire).

The tip portion of the upper plunger 110 (the shaft part protruding from the barrel 130) has the outer diameter smaller than the inner diameter of the small diameter part 41A3 of the upper housing 11A. Further, the tip portion of the lower plunger 120 (the shaft part protruding from the barrel 130) has the outer diameter smaller than the inner diameter of the small diameter part 41B of the lower housing 11B.

The upper plunger 110 and the lower plunger 120 are pushed in directions away from each other by the pushing member 140 and configured to be slidable on the barrel 130.

The probe body 101 illustrated in FIG. 4 is a so-called both-side sliding probe configured such that the upper plunger 110 and the lower plunger 120 slide in direction of the axis X1.

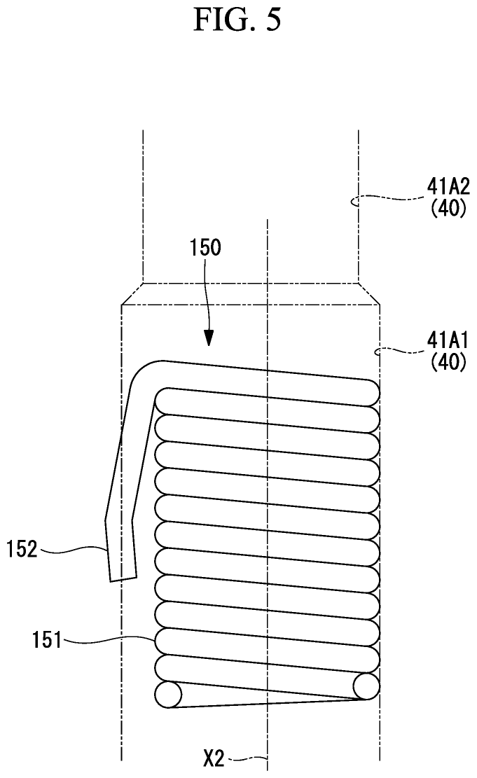

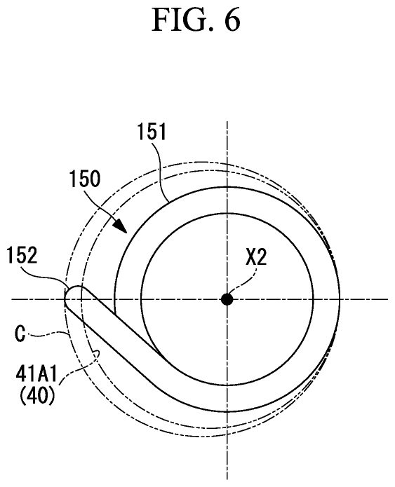

As illustrated in FIG. 5 and FIG. 6, the spring member 150 includes a coil part 151 and a protruding part 152.

The coil part 151 is a cylindrical portion formed of a wired material wound around an axis X2 (second axis).

The coil part 151 has the outer diameter smaller than the inner diameter of the large diameter part 41A1 and larger than the inner diameter of the intermediate diameter part 41A2.

An example of the material of the coil part 151 may be a metal or a resin.

An example of the metal material may be a piano wire, a stainless wire, or a hard steel wire. Further, a tungsten-based or copper alloy-based material may be used.

The protruding part 152 is a portion of a wired material forming the coil part 151 that protrudes outward from the outer circumferential face of the coil part 151.

In the case of FIG. 5 and FIG. 6, the protruding part 152 is formed by extending a wired material located on the top end of the coil part 151 along the tangential direction to protrude outward from the outer circumferential face of the coil part 151 and bending the protruding portion downward along the axis X2.

Note that the “tangential direction” used herein means a direction of a tangent to a circle rendered by the contour of the coil part 151 when the coil part 151 is viewed in planar view in the direction of the axis X2, as illustrated in FIG. 6.

As illustrated in FIG. 5 and FIG. 6, when unloaded, the spring member 150 including the protruding part 152 has the outer diameter (the circumscribed circle, namely, the circle represented by C in FIG. 6) larger than the large diameter part 41A1.

However, when the protruding part 152 is elastically deformed by torsion of the coil part 151, the diameter of the circumscribed circle can be reduced to be smaller than the large diameter part 41A1. Accordingly, the spring member 150 can be accommodated in the large diameter part 41A1.

As illustrated in FIG. 2, the probe body 101 is inserted into the coil part 151 of the spring member 150, and thereby the probe 100 is configured.

### Assembly Method of Probe and Socket

An assembly method of the probe 100 and the socket 10 will be described below.

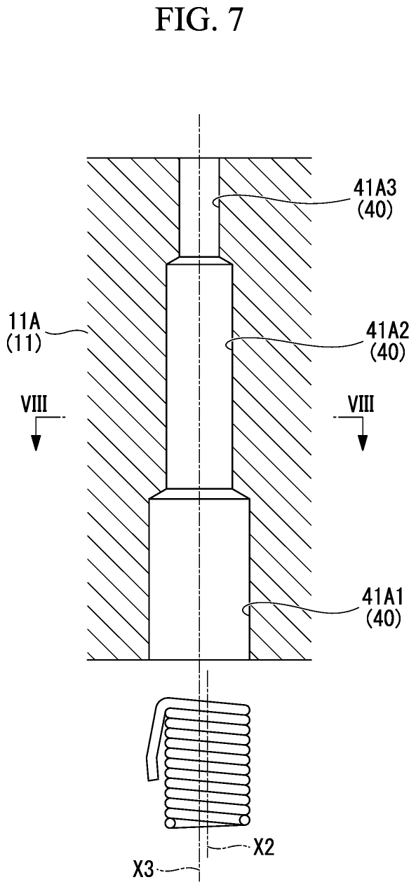

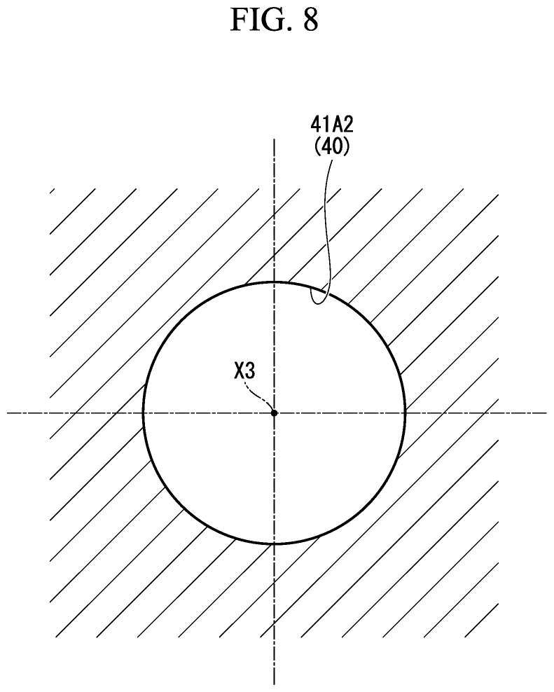

First, as illustrated in FIG. 7 and FIG. 8, the spring member 150 is inserted along the direction of the axis X3 from below into the large diameter part 41A1 formed in the upper housing 11A.

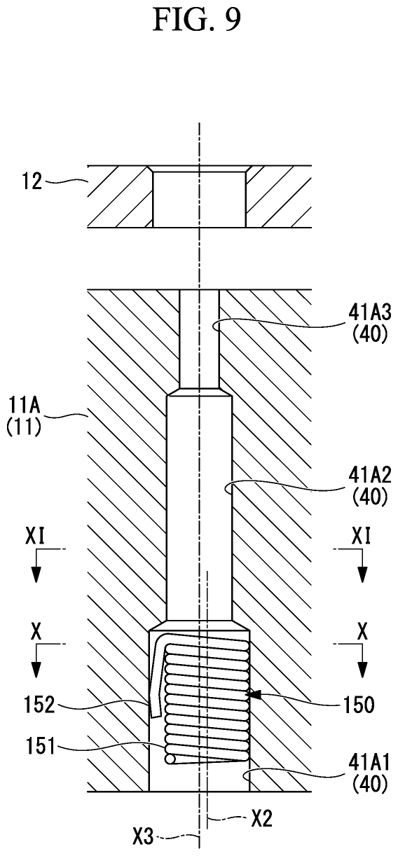

At this time, as illustrated in FIG. 9 to FIG. 11, the protruding part 152 of the spring member 150 is elastically deformed by torsion of the coil part 151, and thereby the spring member 150 is accommodated in the large diameter part 41A1.

Note that, since the outer diameter of the coil part 151 is larger than the inner diameter of the intermediate diameter part 41A2, the spring member 150 is retained in the large diameter part 41A1.

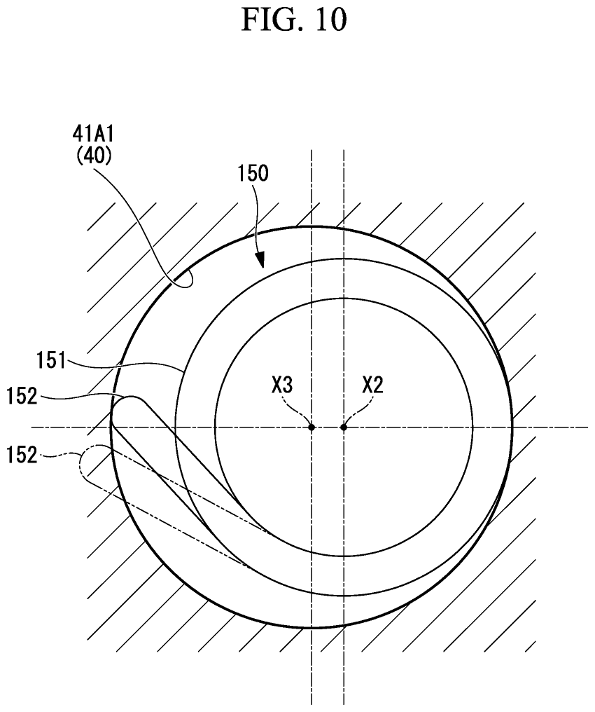

As illustrated in FIG. 9 and FIG. 10, the coil part 151 and the protruding part 152 of the spring member 150 accommodated in the large diameter part 41A1 are in elastic contact with the inner circumferential wall defining the large diameter part 41A1 due to elastic force (restoring force) by which the protruding part 152 tries to return to the original position (see FIG. 6).

Specifically, the coil part 151 and the protruding part 152 are in contact with respective facing portions of the inner circumferential wall. In the case of FIG. 9, the coil part 151 is in contact with the right side of the inner circumferential wall, and the protruding part 152 is in contact with the left side of the inner circumferential wall.

At this time, as illustrated in FIG. 9 to FIG. 11, because the coil part 151 has been moved by the restoring force of the protruding part 152, the axis X2 of the coil part 151 is offset from the axis X3 of the through-hole 40 (in this case, the large diameter part 41A1 and the intermediate diameter part 41A2).

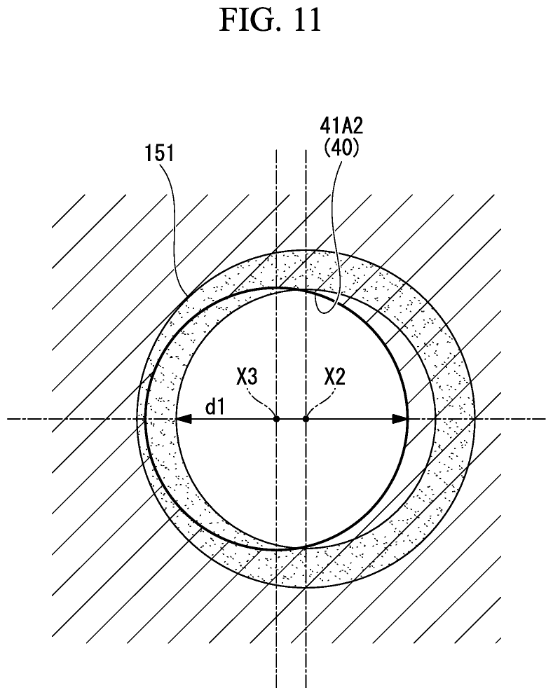

Further, as illustrated in FIG. 11, in a direction passing through the axis X2 and the axis X3, the inner diameter of the coil part 151 and the inner diameter of the intermediate diameter part 41A2 overlap each other by a distance dl at the maximum. In other words, when the intermediate diameter part 41A2 is viewed in planar view in the direction of the axis X2 and the axis X3, there is an opening of the distance dl at the maximum.

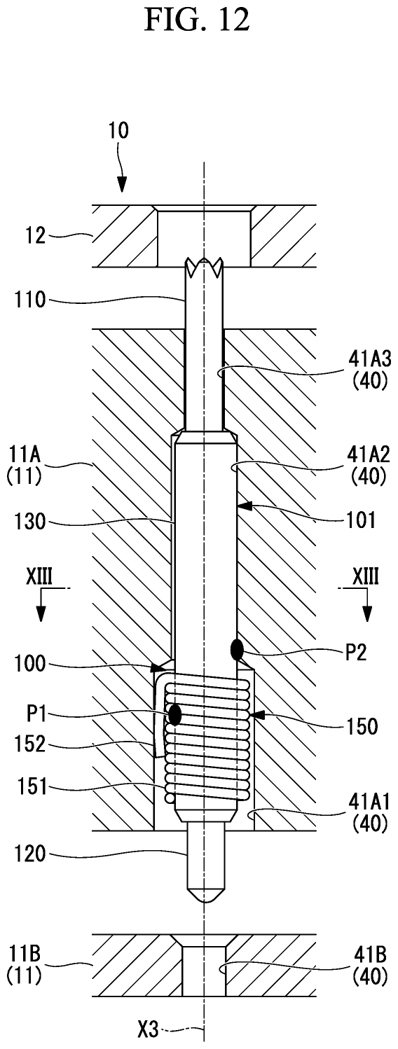

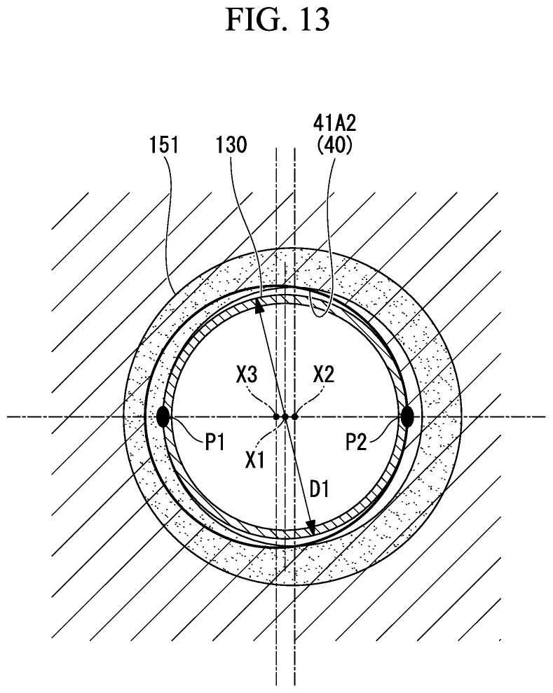

Note that, for the spring member 150 illustrated in FIG. 11, only the coil part 151 is represented, and the protruding part 152 is omitted for simplified illustration. Next, as illustrated in FIG. 12 and FIG. 13, the probe body 101 is inserted into the through-hole 40 along the direction of the axis X3, and inserted into the coil part 151 along the direction of the axis X2.

At this time, the through-hole 40, the probe body 101, and the spring member 150 have the following relationship when each dimension is set in advance so that the outer diameter D1 of the barrel 130 is larger than the distance d1.

When the barrel 130 is inserted into the coil part 151, the coil part 151 is moved by the difference between D1 and d1. Herein, it is found from comparison between FIG. 11 and FIG. 13 that, when the position of the axis X3 is defined as a reference, the coil part 151 is moved from the right side to the left side, and the amount of the offset of the axis X2 from the axis X3 becomes smaller. Further, it is found that the axis X1 of the probe body 101 is located between the axis X2 and the axis X3.

Because the coil part 151 has been pressed against the inner circumferential wall of the large diameter part 41A1 (the right portion in FIG. 12 and FIG. 13) by the protruding part 152, the inner circumferential face of the coil part 151 (the left portion in FIG. 12 and FIG. 13) is in contact with the outer circumferential face of the barrel 130 at the contact point P1 when the barrel 130 is inserted.

At the same time, the barrel 130 subjected to the rightward force from the contact point P1 is pressed against the inner circumferential wall defining the intermediate diameter part 41A2 (the right portion in FIG. 12 and FIG. 13) by the elasticity of the protruding part 152 and is in direct contact with the housing 11 (the upper housing 11A) at the contact point P2.

Accordingly, the probe 100 in electrical conduction with the upper housing 11A is assembled.

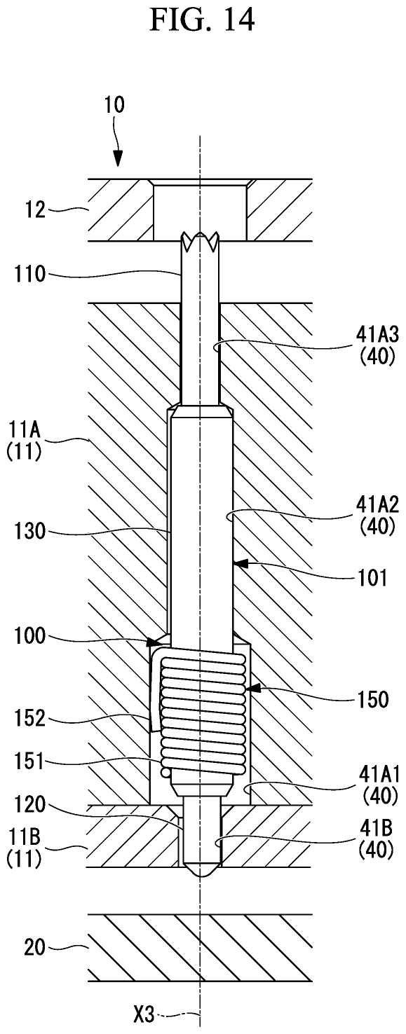

Next, as illustrated in FIG. 14, the lower housing 11B is installed from below the upper housing 11A. Accordingly, the socket 10 is assembled.

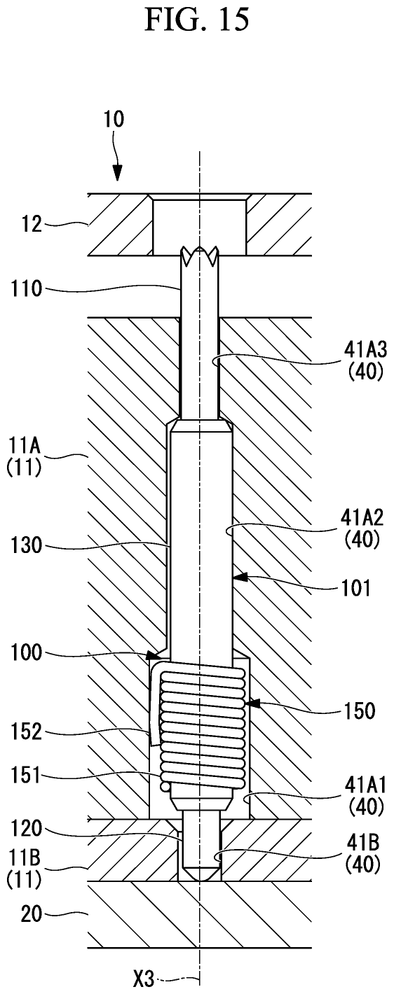

Next, the socket 10 is mounted on the printed wiring board 20 as illustrated in FIG. 15, and the IC package 30 is then placed on the movable base 12 as illustrated in FIG. 16. Accordingly, inspection of the IC package 30 is ready.

### Another Form of Spring Member

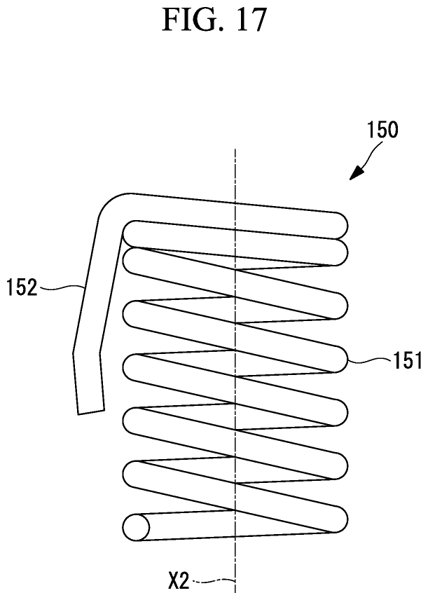

The spring member 150 may take forms as illustrated in FIG. 17 to FIG. 22 as examples other than the form illustrated in FIG. 5 and FIG. 6.

Modified examples of the spring member 150 will be described below.

### Modified Example 1

As illustrated in FIG. 17, turns of the wired materials wound around the coil part 151 may be spaced from each other in the direction of the axis X2 to form the spring member 150 that exerts elastic force also in the compression direction along the axis X2.

### Modified Example 2

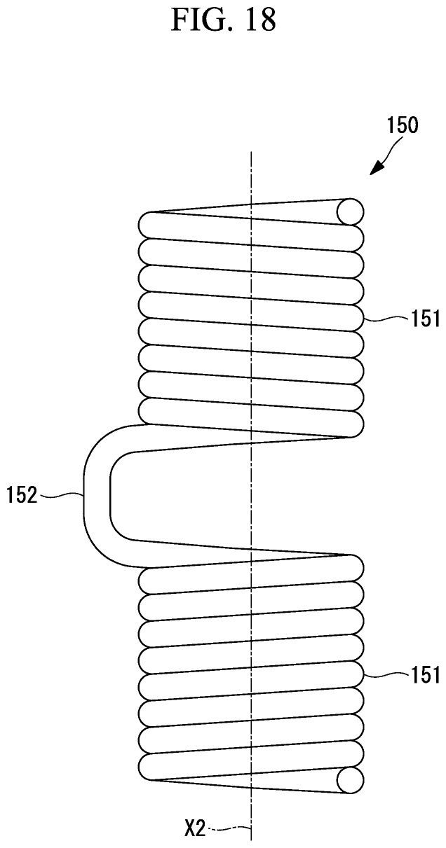

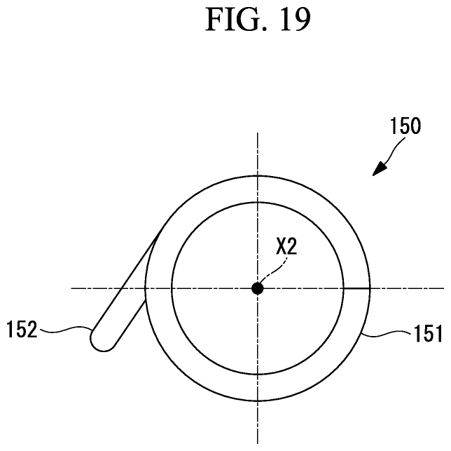

As illustrated in FIG. 18 and FIG. 19, a plurality of coil parts 151 may be arranged adjacent to each other in the direction of the axis X2 to form the spring member 150 in which the lower end of the coil part 151 located above and the upper end of the coil part 151 located below are connected by a C-shaped protruding part 152.

Note that, in this spring member 150, respective coil parts 151 and the protruding part 152 are formed of a single continuous wired material.

### Modified Example 3

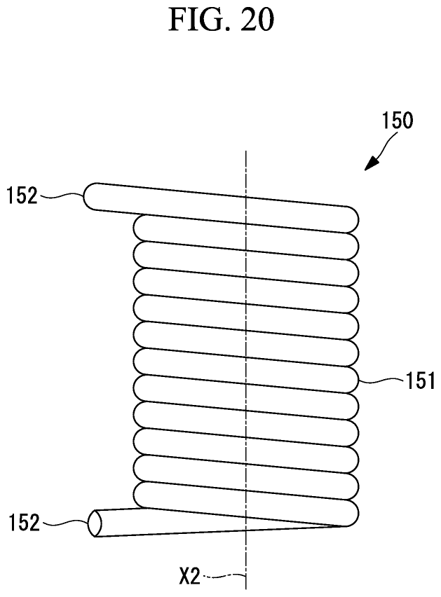

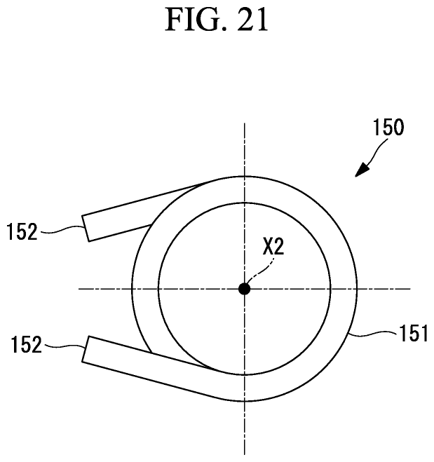

As illustrated in FIG. 20 and FIG. 21, the wired material located at both ends of the upper end and the lower end of the coil part 151 may be extended along the tangential directions to form the spring member 150 forming two protruding parts 152.

Accordingly, the barrel 130 can be stably and forcefully pressed against the inner circumferential wall defining the intermediate diameter part 41A2.

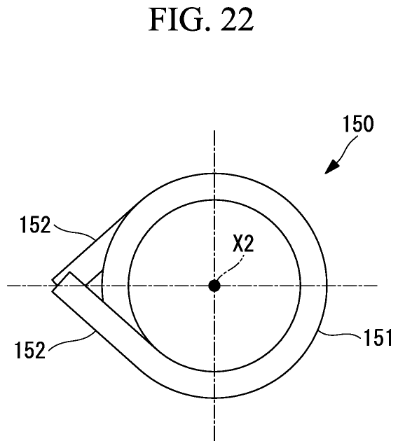

In the case of this spring member 150, as illustrated in FIG. 21, it is required to direct the tips of respective protruding parts 152 in the same direction in advance. Further, it is preferable to form respective protruding parts 152 such that respective protruding parts 152 are inclined relative to each other when the spring member 150 is viewed in planar view. Furthermore, as illustrated in FIG. 22, it is preferable to form respective protruding parts 152 such that the tips of respective protruding parts 152 intersect each other when the spring member 150 is viewed in planar view. Accordingly, it is possible to match the directions in which the restoring forces exerted by respective protruding parts 152 act, that is, the directions in which respective protruding parts 152 move the coil part 151.

According to the present embodiment, the following advantageous effects are achieved.

The spring member 150 includes the coil part 151 and the protruding part 152 that protrudes outward from the outer circumferential face of the coil part 151 and is elastically contacted with the inner circumferential wall defining the through-hole 40 (large diameter part 41A1), and the coil part 151 presses the probe body 101 against the inner circumferential wall by the elasticity of the protruding part 152. Thus, when a clearance is present between the through-hole 40 and the probe body 101, the barrel 130 can be in direct contact with the housing 11. Accordingly, electrical conduction between the probe body 101 and the housing 11 can be ensured.

Further, the protruding part 152 of the spring member 150 is elastically contacted with the inner circumferential wall defining the large diameter part 41A1. Thus, even when the clearance between the through-hole 40 and the barrel 130 is not constant depending on individuals because of a dimensional error of the through-hole 40 or the barrel 130, such error can be absorbed. Therefore, high dimensional accuracy is not required in molding the through-hole 40 or manufacturing the barrel 130.

Further, since the embodiment does not take a configuration to have electrical conduction via the spring member 150, electrical conductivity or excellent electrical conductivity is not required for the spring member 150 itself. This increases the choice of the material or the manufacturing method of the spring member 150 and can reduce costs. For example, the spring member 150 can be made of an inexpensive resin. Further, it is not required to apply gold plating to the spring member 150 in order to stabilize the contact resistance, and it is thus possible to reduce costs by the cost for the absence of plating.

Further, in case of using the spring member 150 including two coil parts 151 adjacent to each other in the direction of the axis X2 and including the protruding part 152 provided between one coil part 151 and the other coil part 151 adjacent thereto, the probe body 101 can be pressed against the inner circumferential wall by the two coil parts 151. In other words, force for pressing the probe body 101 against the inner circumferential wall is applied to two positions of the barrel 130. Accordingly, the probe body 101 can be stably pressed against the inner circumferential wall. In other words, the probe body 101 can be in stable contact with the inner circumferential wall.

Further, in case of using the spring member 150 including the protruding parts 152 provided at both ends of the coil part 151, the spring member 150 can be in contact with the inner circumferential wall by the protruding parts 152 at two positions spaced away from each other in the axis X2 directions. Accordingly, the barrel 130 can be stably and forcefully pressed against the inner circumferential wall. Further, it is possible to prevent the spring member 150 from inclining inside the through-hole 40 (the large diameter part 41A1).

Further, in case of using the spring member 150 in which tips of the protruding parts 152 intersect each other when viewed in the axis X2 direction, it is possible to match the directions in which the restoring forces exerted by respective protruding parts 152 act.

### Second Embodiment

A probe and a socket for inspection according to a second embodiment of the present invention will be described below with reference to the drawings.

The present embodiment differs from the first embodiment in the form of the barrel and the upper housing and is common to the first embodiment in other respects. Thus, detailed description for the common features will be omitted with only labeling of references of combination of 200s and the same last two digits as in the first embodiment.

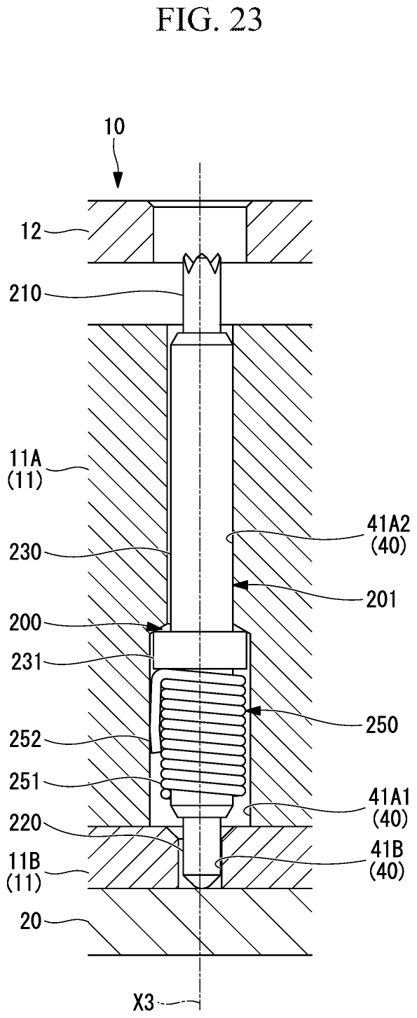

As illustrated in FIG. 23, the barrel 230 of the probe body 201 includes a flange 231.

The flange 231 is a portion protruding outward in the radial direction of the outer circumferential face of the barrel 230.

The flange 231 may be formed around the entire circumference or may be formed partially in the circumferential direction about the axis X1.

The flange 231 has the outer diameter smaller than the inner diameter of the large diameter part 41A1 and larger than the inner diameter of the intermediate diameter part 41A2.

As illustrated in FIG. 2, in the first embodiment, the small diameter part 41A3 is provided in the through-hole 40 of the upper housing 11A, and the outer diameter of the barrel 130 is larger than the inner diameter of the small diameter part 41A3, which prevents the barrel 130 from flying out of the upper housing 11A.

However, as with the probe body 201 illustrated in FIG. 23, the flange 231 is formed on the barrel 230, and this causes the flange 231 to abut against the step at the boundary between the large diameter part 41A1 and the intermediate diameter part 41A2 (hereafter, simply referred to as the “step of the intermediate diameter part 41A2”). Thus, even without providing the small diameter part 41A3 in the through-hole 40 of the upper housing 11A, it is possible to prevent the barrel 230 from flying out of the upper housing 11A.

### Third Embodiment

A probe and a socket for inspection according to a third embodiment of the present invention will be described below with reference to the drawings.

The present embodiment differs from the second embodiment in the form of the probe and is common to the second embodiment in other respects. Thus, detailed description for the common features will be omitted with only labeling of references of combination of 300s and the same last two digits as in the second embodiment.

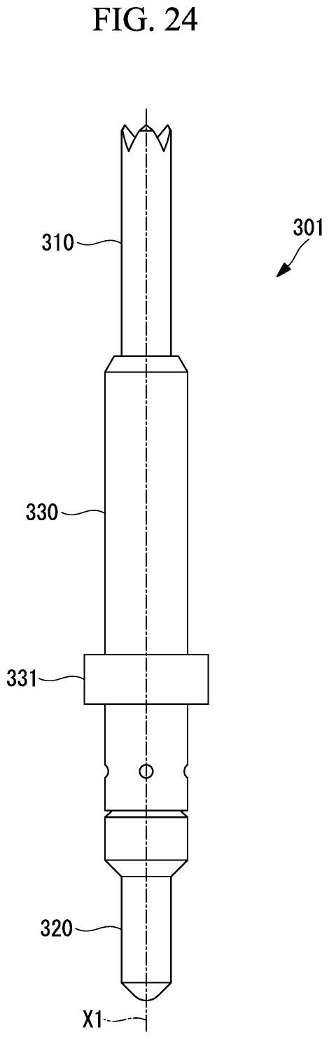

As illustrated in FIG. 24, the probe body 301 is a so-called one-side sliding probe whose lower plunger 320 is fixed to the barrel 330.

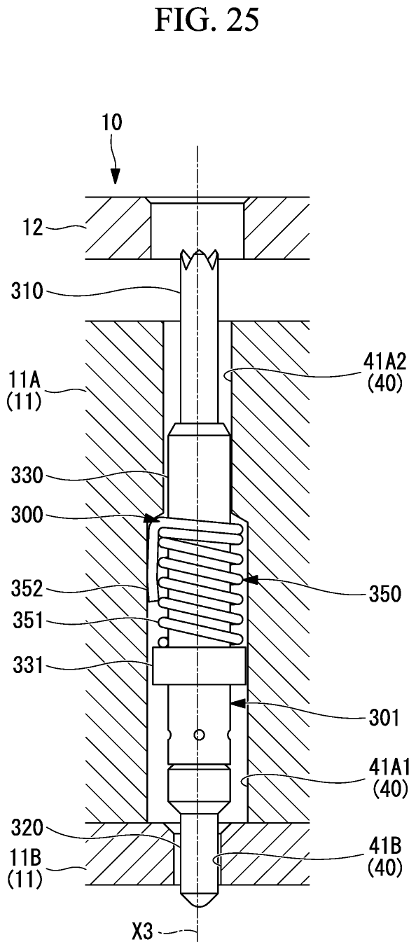

As illustrated in FIG. 25, the probe body 301 is accommodated in the through-hole 40 having the large diameter part 41A1 and the intermediate diameter part 41A2.

In this state, the spring member 350 is accommodated in the large diameter part 41A1 between the flange 331 and the intermediate diameter part 41A2.

The spring member 350 is configured to exert the elastic force also in the compression direction along the axis X2 (see FIG. 17).

The spring member 350 has the upper end configured to abut against the step of the intermediate diameter part 41A2 and the lower end configured to abut against the upper face of the flange 331.

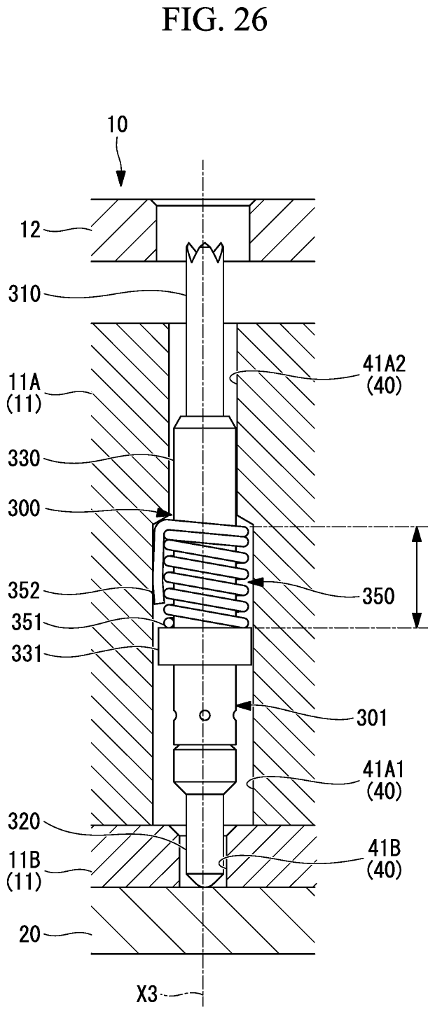

As illustrated in FIG. 26, when the socket 10 in which the probe 300 is accommodated is mounted on the printed wiring board 20, the probe 300 is pushed upward by the printed wiring board 20. At this time, the distance between the upper face of the flange 331 and the step of the intermediate diameter part 41A2 is reduced, and thus the spring member 350 is compressed.

This causes the barrel 330 to be pushed in a direction away from the step of the intermediate diameter part 41A2. As a result, the lower plunger 320 fixed to the barrel 330 is pushed against the printed wiring board 20 (so-called preloading).

### Fourth Embodiment

The present embodiment differs from the first embodiment in the form of the upper housing and is common to the first embodiment in other respects. Thus, detailed description for the common features will be omitted with only labeling of references of combination of 400s and the same last two digits as in the first embodiment.

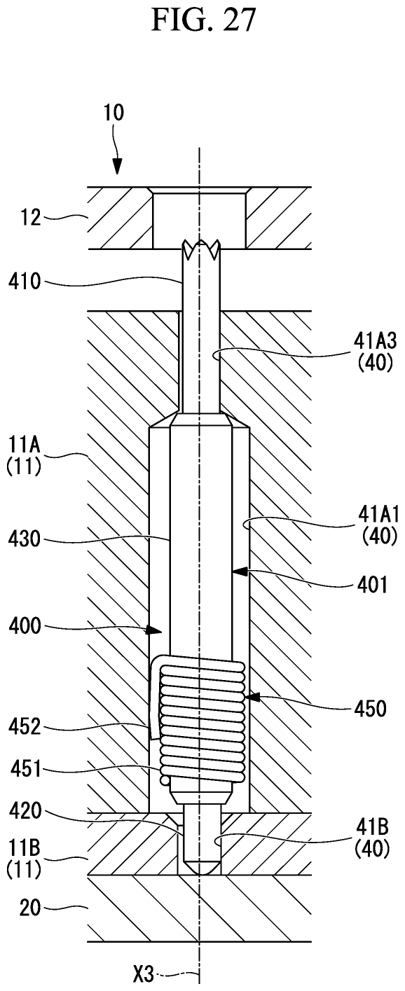

As illustrated in FIG. 27, the through-hole 40 formed in the upper housing 11A has the large diameter part 41A1 and the small diameter part 41A3 but does not have the intermediate diameter part 41A2.

With such a configuration, with respect to the relationship between the probe body 401 and the through-hole 40, the barrel 430 is not in contact with the through-hole 40, but the upper plunger 410 and the lower plunger 420 can be in contact with the inner circumferential wall defining the through-hole 40 (the small diameter part 41A3 and the small diameter part 41B).

Note that the configurations of respective embodiments can be applied to each other within an applicable scope regardless of embodiments.

For example, the shape of the spring member 150 according to the modified example illustrated in the first embodiment may be applied to another embodiment. Further, the probe body 101 of the first embodiment may be configured as a one-side sliding probe.

### REFERENCE SIGNS LIST

10 socket (socket for inspection)
11 housing
11A upper housing
11B lower housing
12 movable base
12a recess
14 base-fixing screw
20 printed wiring board (test board)
30 IC package (inspected device)
40 through-hole
41A1 large diameter part
41A2 intermediate diameter part
41A3 small diameter part
41B small diameter part
100 probe
101 probe body
110 upper plunger
120 lower plunger
130 barrel
140 pushing member
150 spring member
151 coil part
152 protruding part
200 probe
201 probe body
210 upper plunger
220 lower plunger
230 barrel
231 flange
250 spring member
251 coil part
252 protruding part
300 probe
301 probe body
310 upper plunger
320 lower plunger
330 barrel
331 flange
350 spring member
351 coil part
352 protruding part
400 probe
401 probe body
410 upper plunger
420 lower plunger
430 barrel
450 spring member
451 coil part
452 protruding part

1. A probe for grounding to be inserted through a through-hole, the through-hole being formed in a housing and defined by a metal inner circumferential wall, the probe comprising:
a probe body including a cylindrical barrel extending in a direction of a first axis and a plunger accommodated in the barrel; and
a spring member through which the barrel is inserted,
wherein the spring member includes at least one coil part wound about a second axis, the barrel being inserted through the coil part in a direction of the second axis, and includes at least one protruding part formed continuously to the coil part and protruding outward from an outer circumferential face of the coil part to be in elastic contact with the inner circumferential wall, and
wherein the coil part is configured to press the probe body against the inner circumferential wall by elasticity of the protruding part.

2. The probe according to claim 1,
wherein the spring member includes two coil parts adjacent to each other in the direction of the second axis, and
wherein the protruding part is provided between one of the coil parts and another one of the coil parts adjacent to the one of the coil parts.

3. The probe according to claim 1, wherein protruding parts are provided at both ends of the coil part in the direction of the second axis.

4. The probe according to claim 3, wherein tips of the protruding parts intersect each other when viewed in the direction of the second axis.

5. A socket for inspection comprising:
a housing in which a through-hole defined by a metal inner circumferential wall is formed along a direction of a third axis; and
the probe according to claim 1 inserted through the through-hole along the direction of the third axis,
wherein the coil part is configured to press the probe body against the inner circumferential wall by elasticity of the protruding part.

6. The socket for inspection according to claim 5,
wherein the barrel includes a flange protruding from an outer circumferential face,
wherein the through-hole includes a small diameter part having a diameter larger than a portion of the barrel except for the flange and smaller than the flange and a large diameter part having a diameter larger than the flange and being continuous to the small diameter part along the direction of the third axis,
wherein the flange is accommodated in the large diameter part of the through-hole, and
wherein the spring member is accommodated in the large diameter part between the flange and the small diameter part.
